(19) United States
(12) Patent Application Publication
(10) Pub. No.: US 2007/0105316 A1
(43) Pub. Date: May 10, 2007

(54) Nanocrystal memory element, method for fabricating the same and memory having the memory element

(75) Inventor: Pei-Ren Jeng, Hsinchu Hsien (TW)

Correspondence Address: BIRCH STEWART KOLASCH & BIRCH, PO BOX 747, FALLS CHURCH, VA, 22040-0747, US

(73) Assignee: Industrial Technology Research Institute, Hsinchu Hsien (TW)

(21) Appl. No.: 11/495,528

(22) Filed: Jul. 31, 2006

(30) Foreign Application Priority Data
Nov. 7, 2005 (TW) 094138938

(51) Int. Cl. H01L 21/336

(52) U.S. Cl. 438/263

(57) ABSTRACT

A nanocrystal memory element and a method for fabricating the same involves repeatedly and alternately depositing, by atomic layer deposition, conductive layers and dielectric layers on a substrate with a tunnel oxide layer formed thereon, forming multiple layers of nanocrystal groups as a result of crystallization of conductive layers in a rapid thermal annealing process, and forming a gate on the top dielectric layer. The nanocrystal groups disposed at any two neighboring levels are separated by one dielectric layer, thus a plurality of nanocrystals formed in an integration layer are disposed at the same level. Barrier widths between a channel and the nanocrystals of the nanocrystal groups disposed at the same level are equal. Therefore, the nanocrystals at the same level are subjected the same electric field when voltage is applied to the gate, resulting in improved transistor performance, enhanced control of threshold voltage, and avoidance of over-erasing.

### FIELD OF THE INVENTION

The present invention relates to a memory device and a method for fabricating the same, and more particularly, to a nanocrystal memory for accessing charges and a method for fabricating the same.

### BACKGROUND OF THE INVENTION

Among existing non-volatile memories, nanocrystal memory is most likely to replace the traditional flash memory. A distinguishing feature of a traditional flash memory is that, in addition to an oxide insulating layer typically formed in a traditional MOSFET, a floating gate is formed in between a gate and a channel in the MOS of the tradition flash memory, such that data are stored by introducing into or removing from the floating gate negative charges. However, a traditional floating gate is designed to achieve electric conduction, using the charges stored in doped polysilicon which forms the floating gate. Therefore, charges will hardly be stored in the doped polysilicon when there is a current leakage from any point of a tunnel oxide layer beneath the polysilicon floating gate. Moreover, the tunnel oxide layer will have to be thinned down if the size of the memory is to be reduced. However, whatever thinning-down effort is subject to the physical limit of direct tunneling, thus a thinning down process does have its own limit.

Therefore, a nanocrystal memory is proposed to overcome the drawbacks of high operational voltage and slow reading speed as found in the traditional flash memory and enhance memory retention. Unlike the doped polysilicon floating gate of the traditional flash memory, the proposed nanocrystal memory has charges stored in each nanocrystal; in the event of a current leakage from any point of the tunnel oxide layer, only the charges close to the leakage point will get lost, but the rest of the charges will still be confined to individual nanocrystals, because the nanocrystals are separated from one another. Accordingly, the proposed doped polysilicon floating gate overcomes the drawback of the prior art, that is, charge storage is difficult in the presence of a current leakage from any point of the tunnel oxide layer underlying the floating gate.

However, the most important issue that existing technology has to address is about the control of the formation of nanocrystals during a nanocrystal fabrication process. For instance, it will be impossible to store enough charges in a nanocrystal layer disposed with nanocrystals, if the nanocrystals disposed in the nanocrystal layer are too small or over-dispersed; as a result, the charges present in a channel beneath an oxidation layer decrease, causing difficulty in interpretation. In other words, in the event that few charges are stored in the nanocrystal layer, there will be a negligible difference between a threshold voltage associated with the presence of nanocrystals in the nanocrystal layer and a threshold voltage associate with the absence of nanocrystals from the nanocrystal layer, and in consequence it is impossible to determine whether charges are stored in the nanocrystal layer and perform effective interpretation. Accordingly, a nanocrystal fabrication process should be preferably provided with sufficient nanocrystals to store charges so as to create a significant difference between the threshold voltage associated with the presence of charge storage and the threshold voltage associated with the lack of charge storage, thereby enabling the memory to perform effective interpretation.

At present, an existing method for storing sufficient charges involves sputtering, depositing or implanting a thick layer of metal ions, and then performing annealing to form nanocrystals in a silicide layer. The drawback of the method is poor control over the levels and positions of the nanocrystals in the silicide layer and, as a result, the nanocrystals are scattered, making barrier width between the nanocrystals and the gate inconsistent. In consequence it is difficult to keep a writing-related or erasure-related threshold voltage constant. In other words, if nanocrystals are scattered, the distance between the underlying substrate or the tunnel oxide layer and individual nanocrystals will be inconsistent, and in consequence the energy barrier varies from nanocrystal to nanocrystal. Accordingly, by the time a voltage is applied, some nanocrystals have already been stored with charges, but others have not; similarly, by the time an erasure operation is performed, some nanocrystals have already got rid of charges, but others have not. For this reason, interpretation is wrong, which in turn causes over-erasing.

Referring to FIG. 1, a plurality of nanocrystals 106 in a nanocrystal layer 107 embedded in between a gate oxide 104 and a gate 105 of a traditional nanocrystal memory are scattered and unevenly distributed, wherein once a voltage is applied to the gate 105, individual nanocrystals 106 are subjected to electric field of different strengths because individual nanocrystals 106 are separated from the gate 105 by different distances. As a result, it is rather difficult to control transistor threshold voltage. Moreover, nanocrystals with relatively narrow barrier width may be over-erased as a result of an attempt to remove all the charges stored in the nanocrystal 106 during an erasing process.

Therefore, an urgent issue to be addressed involves fabricating a nanocrystal layer with a high density and a uniform distribution.

### SUMMARY OF THE INVENTION

In light of the above drawbacks of the prior art, a primary objective of the present invention is to provide a nanocrystal memory element characterized by uniform distribution of threshold voltage of the nanocrystals and lack of over-erasing and a method for fabricating the same.

Another objective of the present invention is to provide a nanocrystal memory with equal level distribution.

In order to achieve the foregoing and other objectives, the present invention proposes a method for fabricating a nanocrystal memory element, the method comprising the steps of: forming a tunnel oxide layer on a substrate; depositing conductive layers and dielectric layers on the tunnel oxide layer repeatedly and alternately; performing a rapid thermal annealing process to the conductive layers and the dielectric layers, such that a plurality of nanocrystals are formed as a result of crystallization of the conductive layers, and the nanocrystals formed as a result of the crystallization of the same conductive layer are located at the same level; forming an integration layer by combining the conductive layers and the dielectric layers previously treated with the rapid thermal annealing process; and forming a gate on the integration layer.

According to the present invention, a method for fabricating a nanocrystal memory element involves disposing at the same level the nanocrystals formed as a result of the crystallization of any conductive layer such that every nanocrystal has the same barrier width in relation to the gate, with a view to achieving uniform distribution of threshold voltage of the nanocrystals, preventing over-erasing from occurring, and thereby enhancing the performance of the memory.

The present invention further provides a nanocrystal memory element comprising a substrate, a tunnel oxide layer formed on the substrate, an integration layer formed on the tunnel oxide layer, and a gate formed on the integration layer. The integration layer comprises a dielectric material, and nanocrystal groups, each collectively formed by a plurality of nanocrystals located at the same level in the dielectric material, such that distances, and therefore barrier widths, between the tunnel oxide layer and the nanocrystals in the same nanocrystal group are equal.

The present invention further provides a memory comprising the nanocrystal memory element. The memory comprises a substrate, a source and a drain both formed on the substrate and spaced apart by an appropriate distance, a tunnel oxide layer formed on the substrate and disposed between the source and the drain, an integration layer formed on the tunnel oxide layer, and a gate formed on the integration layer. The integration layer comprises a dielectric material, and nanocrystal groups, each collectively formed by a plurality of nanocrystals located at the same level in the dielectric material, such that distances, and therefore barrier widths, between the tunnel oxide layer and the nanocrystals in the same nanocrystal group are equal.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross sectional view of a nanocrystal layer of the traditional nanocrystal memory;

FIG. 2A illustrates formation of a tunnel oxide layer on a substrate;

FIG. 2B, which is similar to the cross-sectional view shown in FIG. 2A, illustrates how conductive layers and dielectric layers are deposited on the tunnel oxide layer repeatedly and alternately;

FIG. 2C, which is similar to the cross-sectional view shown in FIG. 2B, illustrates how to perform a thermal oxidation process, such as a rapid thermal annealing process;

FIG. 2D, which is similar to the cross-sectional view shown in FIG. 2C, illustrates a plurality of nanocrystals formed as a result of crystallization of the conductive layers;

FIG. 2E, which is similar to the cross-sectional view shown in FIG. 2D, illustrates a gate fabricated in a process; and

FIG. 3 is a cross-sectional view of a nanocrystal memory of the present invention.

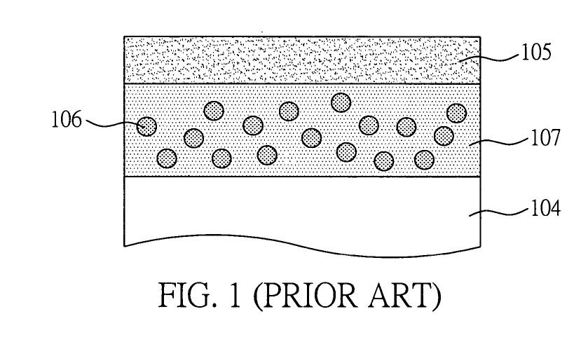

### DETAILED DESCRIPTION OF THE PREFERRED EMBODIMENTS

A nanocrystal memory element, a method for fabricating the same, and the memory with the memory element provided in accordance with the present invention are described with the following specific embodiments and drawings.

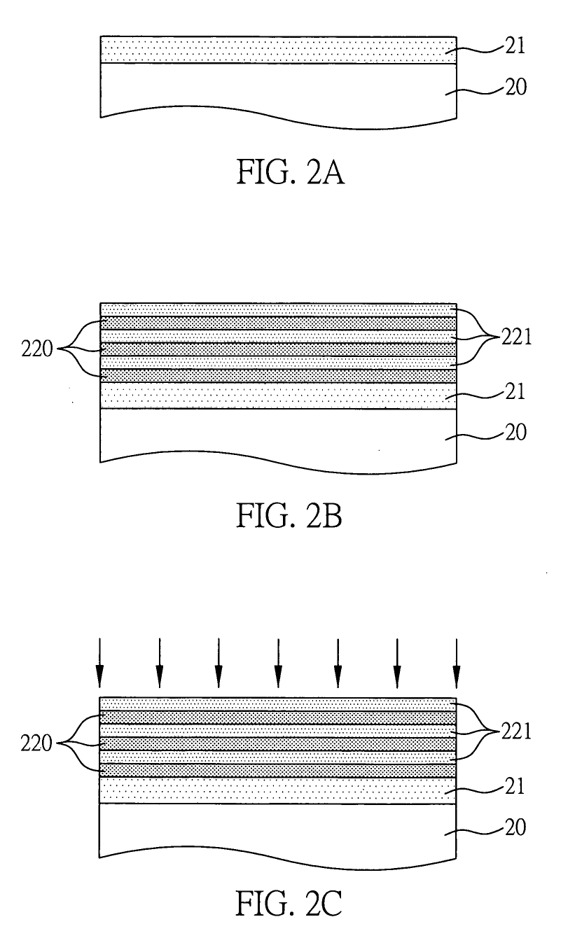

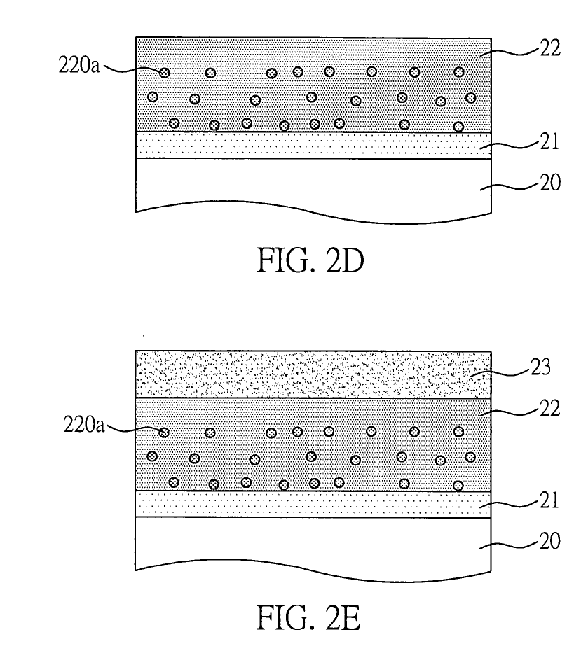

FIGS. 2A to 2E illustrate a method for fabricating a nanocrystal memory element of the present invention.

Referring to FIG. 2A, first of all, a tunnel oxide layer 21 is formed on a substrate 20 made of silicon material by thermal oxidation known in the prior art. The tunnel oxide layer 21 is made of silicon oxides or other dielectric materials and is preferably 5 nanometers thick. The method for forming the tunnel oxide layer 21 is known in the prior art, thus no related detailed description is given in here.

Referring to FIG. 2B, by atomic layer chemical vapor deposition known in the prior art, depositing on the tunnel oxide layer 21 a dielectric layer, then depositing a conductive layer on the dielectric layer, and finally depositing another dielectric layer on the conductive layer, in a way that the thickness of each deposit layer deposited on the tunnel oxide layer is precisely controlled. In so doing, multiple conductive layers 220 and dielectric layers 221 are alternately deposited, such that any two neighboring conductive layers 220 are separated by a dielectric layer 221. In this embodiment, referring to FIG. 2B, three conductive layers 220 and three dielectric layers 221 are alternately disposed. Noteworthily, the number of the conductive layers 220 and the dielectric layers 221 alternately disposed solely depends on requirements for designing a memory element, but is subject to no specific restriction. In addition to atomic layer chemical vapor deposition, examples of a method for depositing the dielectric layers and the conductive layers on the tunnel oxide layer are molecular beam epitaxy (MBE), chemical vapor deposition (CVD), physical vapor deposition (PVD), and other appropriate methods. The dielectric layers 221 are made of conventional dielectric materials, such as silicon oxides. The conductive layers 220 are made of one selected from the group consisting of metals, metallic compounds, and doped silicides. The metals are, namely nickel, gold, silver, and platinum. An example of the metallic compounds is titanium nitride (TiN), and that of the silicides is silicon germanium. The doping impurities are, namely gallium phosphide (GaP), cadmium sulfide (CdS), gallium arsenide (GaAs), and indium phosphide (InP), that is, compounds which result from reactions between a group III element and a group V element, or between a group II element and a group VI element; alternatively, the above-mentioned may be replaced by equivalent doping impurities and equivalent compounds known in the prior art and therefore are not discussed in detail here.

Referring to FIG. 2C, a thermal oxidation process, such as rapid thermal annealing, is performed on the conductive layers 220 and the dielectric layers 221 alternately stacked, such that a plurality of nanocrystals 220a are formed as a result of crystallization of the metals or the doping impurities in the conductive layers 220, so as to form an integration layer 22 by combining the conductive layers 220 with the dielectric layers 221. Referring FIG. 2D, the nanocrystals 220a formed in the same conductive layer 220 within the integration layer 22 are located at the same level and form a nanocrystal group.

Moreover, any two conductive layers 220 are separated by one dielectric layer 221; therefore, the nanocrystal groups formed by crystallizing two neighboring upper-lower conductive layers 220 are also separated by the dielectric material which forms the dielectric layer 221. In other words, all the nanocrystals 220a in the same nanocrystal group are disposed at the same level; distances, and therefore barrier widths, between each nanocrystal 220a and the tunnel oxide layer 21 lies thereunder, are the same. Therefore, the fabricated memory allows threshold voltage to be evenly distributed and prevents the over-erasing of charges, thus enhancing memory performance. In addition, the rapid thermal annealing process is performed at temperature that ranges between 800° C. and 1200° C. However, the rapid thermal annealing process is not the only method for forming the nanocrystals 220a; instead, a nitriding process and other appropriate methods can also be used.

Finally, referring to FIG. 2E, a gate 23 is formed on the integration layer 22. The gate 23 is formed by a conventional method, for example, chemical vapor deposition, and is made of any conventional material, such as doped polysilicon. Fabrication of the memory element of the present invention is completed after the gate 23 is formed.

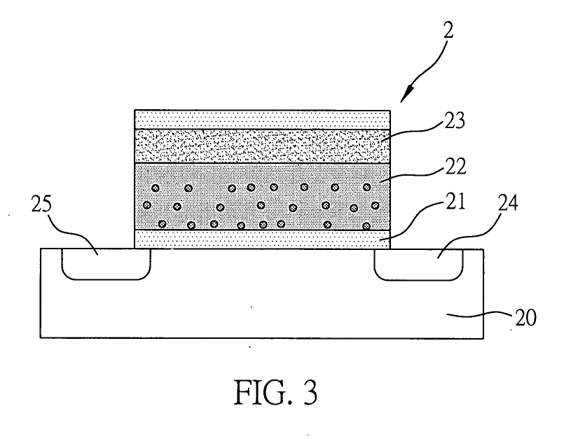

Moreover, FIG. 3 shows a memory 2 into which the foregoing memory element is integrated. As shown in FIG. 3, the memory 2 comprises a substrate 20, a tunnel oxide layer 21 formed on the substrate 20, an integration layer 22 formed on the tunnel oxide layer 21, a gate 23 formed on the integration layer 22, and a source 24 and a drain 25, both formed in the substrate 20, flanking and underlying the tunnel oxide layer 21. In addition, referring to the foregoing description, a plurality of nanocrystals 220a are evenly distributed within the integration layer 22, and the nanocrystals 220a located at the same level form a nanocrystal group. A nanocrystal 220a always belongs to a nanocrystal group formed by the nanocrystals 220a located at a same level, any two neighboring upper-lower nanocrystal groups are separated by a distance.

The present invention is illustrated with the aforesaid embodiments, such that one skilled in the pertinent art can easily understand other advantages and effects of the present invention from the disclosure of the invention. The present invention may also be implemented and applied according to other embodiments, and the details may be modified based on different views and applications without departing from the spirit of the invention.

What is claimed is:

1. A method for fabricating a nanocrystal memory element, the method comprising the steps of:
forming a tunnel oxide layer on a substrate;
depositing conductive layers and dielectric layers on the tunnel oxide layer repeatedly and alternately;
forming a plurality of nanocrystals in the conductive layers, forming an integration layer by combining the conductive layers and the dielectric layers, wherein the nanocrystals which are formed in the same conductive layer are located at a same level and collectively form a nanocrystal group, such that all the nanocrystals in the nanocrystal group are located at the same level; and
forming a gate on the integration layer.

2. The method for fabricating a nanocrystal memory element of claim 1, wherein the steps of depositing the conductive layers and the dielectric layers repeatedly and alternately are performed by means of atomic layer deposition.

3. The method for fabricating a nanocrystal memory element of claim 1, wherein the steps of depositing the conductive layers and the dielectric layers repeatedly and alternately are performed by means of molecular beam epitaxy.

4. The method for fabricating a nanocrystal memory element of claim 1, wherein the steps of depositing the conductive layers and the dielectric layers repeatedly and alternately are performed by means of chemical vapor deposition.

5. The method for fabricating a nanocrystal memory element of claim 1, wherein the steps of depositing the conductive layers and the dielectric layers repeatedly and alternately are performed by means of physical vapor deposition.

6. The method for fabricating a nanocrystal memory element of claim 1, wherein the steps of forming a plurality of nanocrystals in the conductive layers are performed by means of thermal oxidation.

7. The method for fabricating a nanocrystal memory element of claim 6, wherein the thermal oxidation is rapid thermal annealing.

8. The method for fabricating a nanocrystal memory element of claim 1, wherein the dielectric layers are made of a dielectric material.

9. The method for fabricating a nanocrystal memory element of claim 8, wherein the dielectric material is made of silicon oxides.

10. The method for fabricating a nanocrystal memory element of claim 1, wherein any two neighboring upper-lower conductive layers are separated by a dielectric layer interposed therebetween.

11. The method for fabricating a nanocrystal memory element of claim 1, wherein the conductive layers are made of metals.

12. The method for fabricating a nanocrystal memory element of claim 1, wherein the conductive layers are made of metallic compounds.

13. The method for fabricating a nanocrystal memory element of claim 1, wherein the conductive layers are made of doped suicides.

14. A nanocrystal memory element, comprising:
a substrate;
a tunnel oxide layer formed on the substrate;
an integration layer formed on the tunnel oxide layer, wherein a plurality of nanocrystals are disposed in the integration layer such that a nanocrystal always belongs to a nanocrystal group formed by the nanocrystals located at a same level, any two neighboring upper-lower nanocrystal groups are separated by a dielectric material forming the integration layer; and
forming a gate on the integration layer.

15. The nanocrystal memory element of claim 14, wherein distances between the tunnel oxide layer and the nanocrystals in the same nanocrystal group are equal, such that the nanocrystals are disposed at the same level in the integration layer.

16. The nanocrystal memory element of claim 14, wherein the dielectric material of the tunnel oxide layer and the integration layer is made of silicon oxides.

17. A nanocrystal memory, comprising:
a substrate;
a source and a drain both formed on the substrate and spaced apart by an appropriate distance;
a tunnel oxide layer formed on the substrate;
an integration layer formed on the tunnel oxide layer, wherein a plurality of nanocrystals are disposed in the integration layer such that a nanocrystal always belongs to a nanocrystal group formed by the nanocrystals located at a same level, any two neighboring upper-lower nanocrystal groups are separated by a dielectric material forming the integration layer; and
a gate formed on the integration layer.

18. The nanocrystal memory of claim 17, wherein distances between the tunnel oxide layer and the nanocrystals in the same nanocrystal group are equal, such that the nanocrystals are disposed at the same level in the integration layer.

19. The nanocrystal memory of claim 17, wherein the dielectric material of the tunnel oxide layer and the integration layer is made of silicon oxides.
